(19) United States
(12) Patent Application Publication
(10) Pub. No.: US 2025/0096212 A1
(43) Pub. Date: Mar. 20, 2025

(54) POWER SUPPLY MODULE WITH HIGH HEAT DISSIPATION CAPABILITY AND HIGH RELIABILITY, AND INTEGRATED MODULE

(71) Applicant: SHANGHAI METAPWR ELECTRONICS CO., LTD, Shanghai (CN)

(72) Inventors: Qingdong CHEN, Shanghai (CN); Shouyu HONG, Shanghai (CN); Jianhong ZENG, Shanghai (CN); Mingzhun ZHANG, Shanghai (CN)

(73) Assignee: SHANGHAI METAPWR ELECTRONICS CO., LTD, Shanghai (CN)

(21) Appl. No.: 18/890,793

(22) Filed: Sep. 20, 2024

(30) Foreign Application Priority Data
Sep. 20, 2023 (CN) 202311217974.0

(51) Int. Cl. H01L 25/16; H01L 23/00; H01L 23/31; H01L 23/367; H01L 23/495; H01L 23/538; H01L 23/552

(52) U.S. Cl. CPC H01L 25/165; H01L 23/3675; H01L 23/49537; H01L 23/5386; H01L 24/24; H10D 1/20; H01L 23/3107; H01L 23/552; H01L 2224/24195; H01L 2224/24265

(57) ABSTRACT

The invention provides a power supply module with high heat dissipation capability and high reliability. Aiming at the problem that when a power supply module and a system board are fixedly welded, internal welding spots are remelted due to high temperature, on one hand, the structure of the power supply module is further optimized, a device layer is formed in a device in the power supply module through plastic packaging or embedded, an insulating dielectric layer is arranged between the two adjacent device layers, and the device layer and the insulating medium are laminated into an assembly body; the metal interconnection layer is arranged on the surface of the assembly body, and electrical connection between devices in the power supply module is achieved; and no metal welding spot exists in the power supply module, and the assembly reliability of the power supply module and the system is improved.

### CROSS-REFERENCE TO RELATED APPLICATION

This application claims the priority benefit of Chinese application serial no. 202311217974.0, filed on Sep. 20, 2023. The entirety of the above-mentioned patent application is hereby incorporated by reference herein and made a part of this specification.

### BACKGROUND

### Description of Related Art

Along with the increasing demand of artificial intelligence, the computing power demand on the data center is higher and higher, so that the demand of the data center on the power supply power is higher and higher. Under the condition that the size of the system board is certain, the power density of the power supply is required to be higher and higher so as to meet the power requirement of the load. The higher the power density of the power supply, the heat flux density is also increased, so that the thermal resistance of the power supply needs to be further reduced to meet the heat dissipation requirement of the power supply; furthermore, in order to ensure the stable and reliable work of the system, the requirement for the reliability of the power supply is higher and higher.

According to the power supply module structure with high heat dissipation capacity and high reliability, the size and the thermal resistance of the power supply module are reduced in a device stacking mode, the interconnection layer is formed through the metallization process to realize electrical connection between the devices, and the conversion efficiency of the power supply module is improved.

### SUMMARY

In view of the above, one of the objectives of the present invention is to provide a power supply module with high heat dissipation capability and high reliability. The structure of the power supply module is further optimized, and a corresponding simple and reliable process flow is provided.

A power supply module with high heat dissipation capability and high reliability The power supply module is characterized by comprising a switch assembly layer, a magnetic assembly layer, a first connecting layer and a metal interconnection layer; The first connecting layer is arranged between the switch assembly layer and the magnetic assembly layer, the first connecting layer is used for fixedly connecting the switch assembly layer with the magnetic assembly layer, and the first connecting layer is made of an insulating material; the switch assembly layer, the first connecting layer and the magnetic assembly layer are integrally formed through pressing to form an assembly body;

The metal interconnection layer is arranged on the surface of the assembly body, the metal interconnection layer is provided with a plurality of different electrical properties, and the metal interconnection layer wraps at least a part of the top surface, at least a part of the side surface and at least a part of the bottom surface of the assembly body;

The switch assembly layer is electrically connected to the magnetic assembly layer by means of the metal interconnection layer.

Preferably, wherein the switch assembly layer comprises a switch unit, an input capacitor and a first metal wiring layer, the first metal wiring layer is electrically connected to pins of the switch unit and the input capacitor, and the first metal wiring layer is disposed adjacent to the first connecting layer and extends to a side surface of the assembly body and is electrically connected with the metal interconnection layer.

Preferably, wherein the magnetic assembly layer comprises an inductor, an inner hole and a second metal wiring layer, the inductor comprises a winding and a magnetic core, the winding is electrically connected with the second metal wiring layer through the inner hole, and the second metal wiring layer is arranged adjacent to the first connecting layer and extends to the side surface of the assembly body and is electrically connected with the metal interconnection layer.

Preferably, the switch assembly layer comprises a switch unit layer, an input capacitor connection layer and an input capacitor layer, the input capacitor connection layer is arranged between the switch unit layer and the input capacitor layer, and the input capacitor connection layer is used for fixedly connecting the switch unit layer with the input capacitor layer; the switch unit layer, the input capacitor layer and the magnetic assembly layer are respectively provided with pins with different electrical properties; and at least a part of the pins extend to the side surface of the assembly body through the metal wiring layer and are electrically connected with the corresponding metal interconnection layer.

Preferably, wherein the power supply module further comprises a first bonding layer, the first bonding layer is arranged in the first connecting layer, the first bonding layer is used for cross-layer electrical connection of the switch assembly layer and the magnetic assembly layer, the material of the first bonding layer is a conductive high-melting-point material, and the melting point of the first bonding layer is higher than the highest temperature of welding.

Preferably, the power supply module further comprises an output capacitor layer and a second connection layer, the second connection layer is arranged between the output capacitor layer and the magnetic assembly layer, the second connection layer is used for fixedly connecting the output capacitor layer with the magnetic assembly layer, and the second connection layer is made of an insulating material.

Preferably, wherein the output capacitor layer comprises an output capacitor, and the output capacitor layer is provided with a first surface and a second surface which are opposite to each other; the first surface is adjacent to the second connection layer, and a pin of the output capacitor layer is arranged on the second surface.

Preferably, the output capacitor layer is provided with a plurality of layers stacked layer by layer; the switch unit layer, the magnetic assembly layer and the output capacitor layer are respectively provided with pins with different electrical properties; and at least a part of the pins extend to the side surface of the assembly body through the metal wiring layer and are electrically connected with the corresponding electrical metal interconnection layer.

Preferably, the magnetic assembly layer comprises an inductor, an output end inner hole and an output metal wiring layer, and the inductor comprises a winding and a magnetic core; and the winding is electrically connected with the output metal wiring layer through an inner hole of the output end; and the output metal wiring layer horizontally extends to the side surface of the assembly body and is electrically connected with the metal interconnection layer; and the output end inner hole, the output metal wiring layer and the metal interconnection layer form a first output conductive path; the power supply module further comprises a second bonding layer, the second bonding layer is arranged in the second connecting layer, the positions of the output end inner hole, the second bonding layer and the winding vertically correspond, the output end inner hole and the second bonding layer form a second output conductive path; and the first output conductive path and the second output conductive path are connected in parallel; and the material of the second bonding layer is a conductive high-melting-point material, and the melting point of the second bonding layer is higher than the highest temperature of the power supply module welded with the system board.

Preferably, the output capacitor layer comprises a copper column, the positions of the output end inner hole, the second bonding layer and the copper column vertically correspond, the output end inner hole, the second bonding layer and the copper column form a second output conductive path; and the first output conductive path and the second output conductive path are connected in parallel.

Preferably, the switch assembly layer, the first connecting layer, the magnetic assembly layer, the second connection layer and the output capacitor layer are integrally formed through lamination.

Preferably, wherein the metal interconnection layer comprises a GND interconnection layer, a Vin+interconnection layer, a plurality of SW interconnection layers, Vo+interconnection layers and a plurality of signal interconnection layers; the switch assembly layer comprises a plurality of switch units; the magnetic assembly layer comprises an inductor, and the inductor comprises a magnetic core and a plurality of windings; and the switch unit, the SW interconnection layer, the winding and the Vo+interconnection layer are in one-to-one correspondence.

Preferably, the power supply module is provided with a first side surface, a second side surface, a third side surface and a fourth side surface which are adjacent in sequence; the GND interconnection layer covers at least a part of the second side surface, the Vin+interconnection layer covers at least a part of the first side surface and at least a part of the third side surface, and the signal interconnection layer covers at least a part of the fourth side surface; and the SW interconnection layer and the Vo+interconnection layer are arranged at corners defined by the Vin+interconnection layer and the GND interconnection layer.

Preferably, the magnetic assembly layer comprises an inductor, a plurality of inner holes and a plurality of second metal wiring layers, and each inductor comprises a winding, a magnetic core and at least two inductor integrated copper foils; the inductor is electrically connected with the second metal wiring layer through an inner hole, and the second metal wiring layer is arranged on the top surface of the magnetic assembly and extends to the side surface of the assembly body and is electrically connected with the metal interconnection layer; and the inductor integrated copper foil includes the first inductor integrated copper foil and the second inductor integrated copper foil; and the inductor is provided with a first inductor side surface, a second inductor side surface, a third inductor side surface and a fourth inductor side surface corresponding to the four side surface directions of the power supply module; the first inductor integrated copper foil wraps at least a part of the second inductor side surface; the second inductor integrated copper foil wraps at least a part of the fourth inductor side surface; the input end of the winding is electrically connected from the top surface SW interconnection layer of the magnetic assembly; the first inductor integrated copper foil is electrically connected with the Vin+interconnection layer; and the second inductor integrated copper foil is electrically connected with the GND interconnection layer.

Preferably, at least a part of the first side surface of the inductor is wrapped by one of a first inductor integrated copper foil or a second inductor integrated copper foil; and at least a part of the third side surface of the inductor is wrapped by one of a first inductor integrated copper foil or a second inductor integrated copper foil.

Preferably, the magnetic assembly layer further comprises a plurality of output inner holes and a plurality of output metal wiring layers; the inductor is electrically connected with the output metal wiring layer through an output inner hole, and the output metal wiring layer is arranged on the bottom surface of the magnetic assembly layer and extends to the side surface of the assembly body and is electrically connected with the metal interconnection layer; the output end of the winding is electrically connected with the Vo+interconnection layer from the bottom surface of the magnetic assembly; the first inductor integrated copper foil is electrically connected with the Vin+interconnection layer from the top surface and the bottom surface of the magnetic assembly respectively; and the second inductor integrated copper foil is electrically connected with the GND interconnection layer from the top surface and the bottom surface of the magnetic assembly.

An integrated module with high heat dissipation capability and high reliability is characterized by comprising 2N power supply modules; the power supply modules are electrically connected in parallel; the power supply modules are paired in pairs, each pair of power supply modules share one side surface, the metal interconnection layer comprises a signal interconnection layer, and the signal interconnection layer is arranged on a shared side surface; and N is a natural number.

Preferably, a connection position is arranged between two adjacent pairs of power supply modules, and the connection position is made of an insulating material.

Preferably, the signal interconnection layer is a through-hole electroplated layer.

Preferably, a signal wiring layer is arranged at the bottom of the signal interconnection layer, and the signal wiring layer is used for summarizing the wiring of the signal interconnection layer of each power supply module.

Preferably, a pin wiring layer is arranged at the bottom of the integrated module.

Preferably, a welding ball is arranged at the bottom of the power supply module, the welding ball includes at least four supporting welding balls, and the at least four supporting welding balls are arranged at four corners of the bottom of the integrated module.

Preferably, wherein the support welding ball is a copper alloy ball coated with a tin layer

Compared with the prior art, the application has the following beneficial effects:

(1) The invention provides a power supply module, so that no metal welding spot exists in the power supply module, and each assembly layer fan out the pin to the side surface of the module and can realize cross-layer interconnection through the metal interconnection layer, so that when the power supply module and the system board are welded and fixed, the internal device of the power supply module is not influenced by welding high temperature; and the power supply module is easy to integrate through a plurality of parallel connection.

(2) The invention provides a process flow, so that the production process of the power supply module with high heat dissipation capability and high reliability is simple, convenient and reliable.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic circuit diagram of a power supply module;

FIG. 1B is a schematic top view of a power supply module 1a;

FIG. 1C is a bottom schematic diagram of a power supply module 1a;

FIG. 1D is an internal top view of the switch assembly layer;

FIG. 1E is a side cross-sectional view of a power supply module;

FIG. 2A to FIG. 2I are schematic diagrams of a process flow I;

FIG. 3 is a vertical power supply structure;

FIG. 4 is a side cross-sectional view of a power supply module 1b;

FIG. 5A to FIG. 5E are schematic diagrams of a process flow II;

FIG. 6A to FIG. 6C are schematic structural diagrams of an integrated module;

FIG. 7A is a schematic diagram of a partial current path in a power supply module 1b;

FIG. 7B is a schematic diagram of a partial current path in the power supply module 1c;

FIG. 8A to FIG. 8F are schematic diagrams of a process flow III;

FIG. 9A is a side cross-sectional view of a power supply module 1d;

FIG. 9B is a schematic cross-sectional view of a power supply module 1d;

FIG. 10 is a schematic structural diagram of another power supply module; and

FIG. 11 is another vertical power supply structure.

### DESCRIPTION OF THE EMBODIMENTS

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

One of the cores of the invention is to provide a power supply module with high heat dissipation capability and high reliability. On one hand, the structure of the power supply module is further optimized, a device layer is formed in the power supply module through plastic packaging or embedded, an insulating dielectric layer is arranged between the two adjacent device layers, and the device layer and the insulating dielectric are laminated into an assembly body; the metal interconnection layer is arranged on the surface of the assembly body, so that electrical connection between devices in the power supply module is realized; and no metal welding spot exists in the power supply module, and the assembly reliability of the power supply module and the system is improved. On the other hand, a corresponding simple and reliable process flow is provided.

The technical solutions in the embodiments of the present disclosure will be clearly and completely described below with reference to the accompanying drawings in the embodiments of the present disclosure. All other embodiments obtained by a person of ordinary skill in the art based on the embodiments of the present invention without creative efforts shall fall within the protection scope of the present invention.

The power supply module 1 comprises an input positive terminal Vin+, an output positive terminal Vo+, a grounding terminal GND, switch units 211 and 212, a magnetic assembly 10, an input capacitor Cin and an output capacitor Co, wherein the input capacitor Cin is bridged between the input positive terminal Vin+ and the grounding terminal GND, and the output capacitor Co is bridged between the output positive terminal Vo+ and the grounding terminal GND; and each power switch unit comprises an input positive pin, an SW pin and a grounding pin which are electrically connected with the input positive terminal Vin+, the SW1/SW2 and the grounding terminal GND respectively, and each power switch unit further comprises a plurality of signal pin positions Signal. The magnetic assembly 10 comprises two inductors L1 and L2, the inductors L1 and L2 are magnetically coupled by means of the same magnetic core, the inductor L1 is bridged between the SW1 and the output positive terminal Vo1+, the inductor L2 is bridged between the SW2 and the output positive terminal Vo2+, and the output positive terminal Vo1+ and Vo2+ are electrically connected in parallel to form an output positive terminal Vo+.

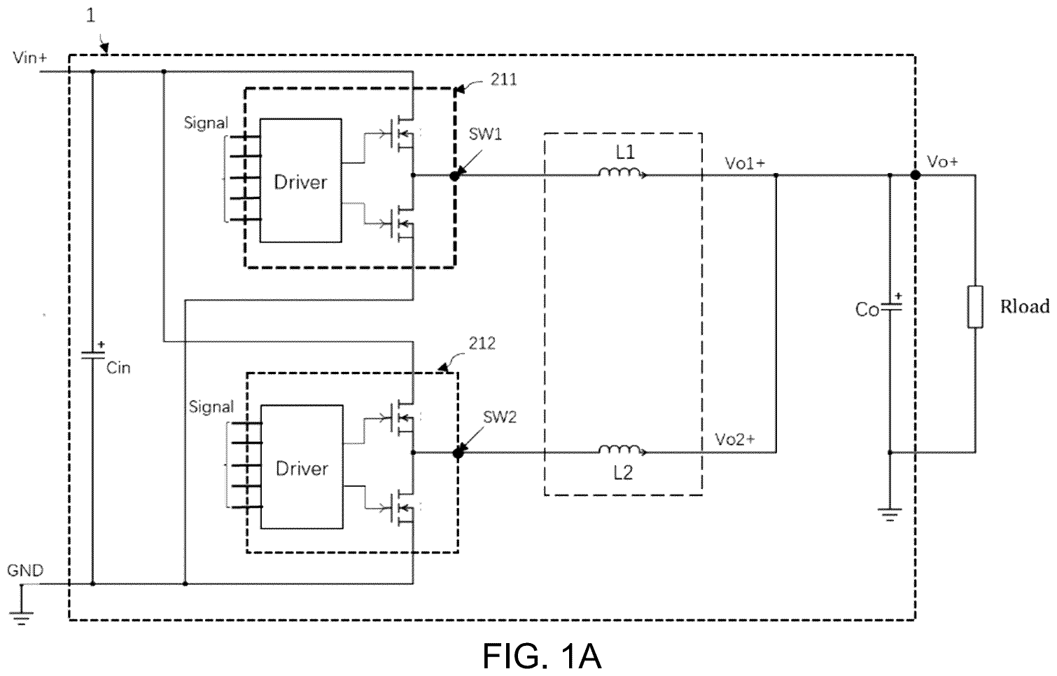

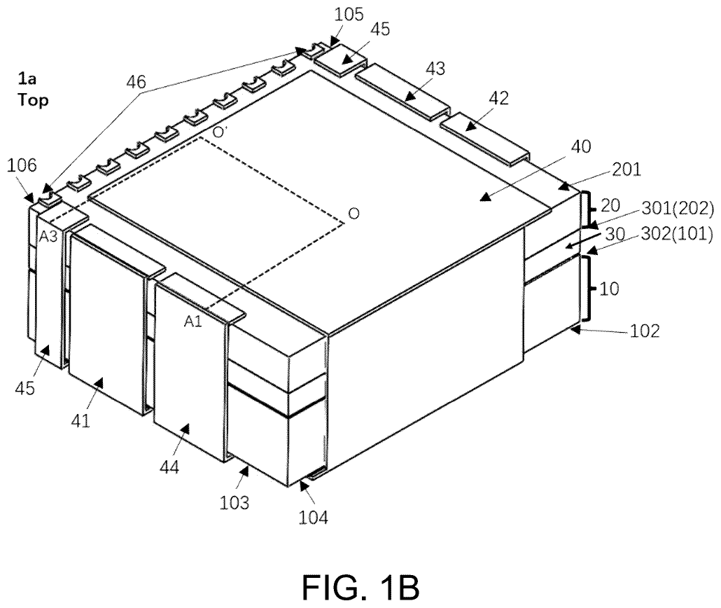

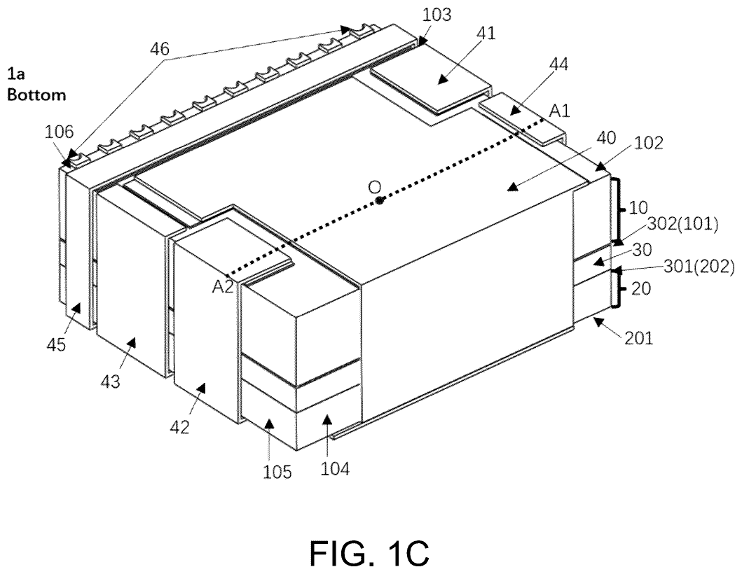

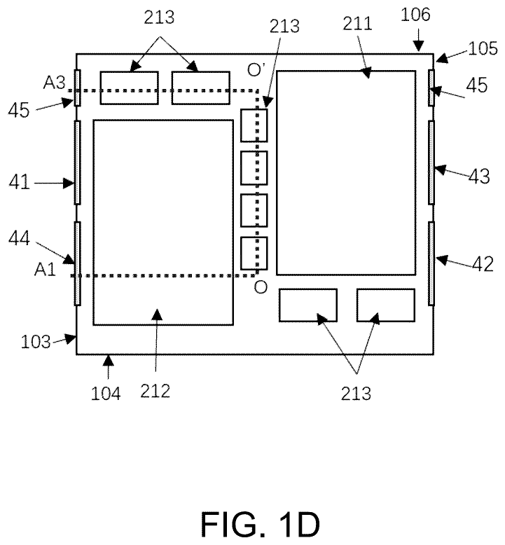

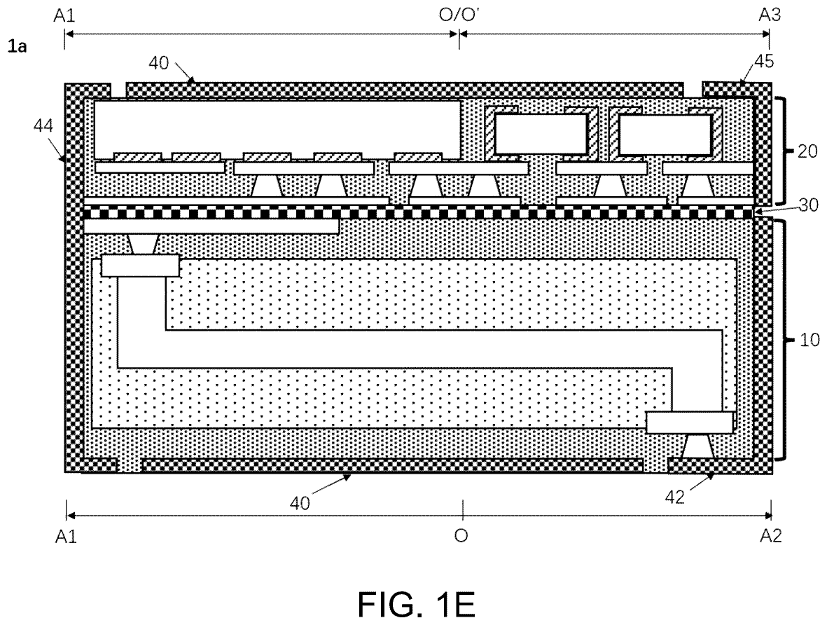

The invention provides a power supply module structure 1a with high heat dissipation capability and high reliability, as shown in FIG. 1B and FIG. 1C, the top view three-dimensional schematic diagram of the power supply module structure 1a is shown in FIG. 1B, and the bottom view three-dimensional schematic diagram of the power supply module structure 1a is shown in FIG. 1C. The power supply module structure 1a comprises a switch assembly layer 20, a magnetic assembly layer 10, a first connecting layer 30, a GND interconnection layer 40, a Vo1+interconnection layer 41, a Vo2+interconnection layer 42, an SW1 interconnection layer 43, a SW2 interconnection layer 44 and a Vin+interconnection layer 45, wherein the GND interconnection layer 40, the Vo1+interconnection layer 41, the Vo2+interconnection layer 42, the SW1 interconnection layer 43, the SW2 interconnection layer 44 and the Vin+interconnection layer 45 are collectively referred to as a metal interconnection layer. The first connecting layer 30 comprises a first face 301 and a second face 302 opposite to each other, the switch assembly layer 20 is arranged adjacent to the first face 301, and the magnetic assembly layer 10 is arranged adjacent to the second face 302; the first connecting layer 30 is used for fixedly connecting the switch assembly layer 20 and the magnetic assembly layer 10, and the first connecting layer 30 is made of an insulating material; the power supply module structure 1a comprises a top surface 201 (equivalent to a first surface 201 of the switch assembly layer 20), a bottom surface 102 (equivalent to a second surface 102 of the magnetic assembly layer 10) and four side surfaces 103/104/105/106, wherein each metal interconnection layer wraps the top surface 201, one side surface and the bottom surface 102 of the power supply module structure; the GND interconnection layer 40 wraps the top surface 201, the side surface 104 and the bottom surface 102, the Vo1+interconnection layer 41, the SW2 interconnection layer 44 and the Vin+interconnection layer 45 respectively wrap the top surface 201, the side surface 103 and the bottom surface 102, and the Vo2+interconnection layer 42, the SW1 interconnection layer 43 and the Vin+interconnection layer 45 respectively wrap the top surface 201, the side surface 105 and the bottom surface 102, and the power supply module structure 1a further comprises a plurality of signal electrical connectors 46 which are arranged adjacent to the side surface 106 of the power supply module structure 1a to realize electric connection between the switch assembly layer 20 and the bottom surface 102 of the power supply module structure 1a. In the other embodiments, the Vo1+interconnection layer 41 and Vo2+interconnection layer 42 can be combined to one Vo+interconnection layer.

FIG. 1D is an internal top view of the switch assembly layer 20. The switch assembly layer 20 comprises switch units 211 and 212 and an input capacitor 213. The switch unit 212 is disposed adjacent to the side surface 103. The power switch unit 211 is disposed adjacent to the side surface 105. Some of the input capacitors 213 are disposed adjacent to the side surfaces 104 and 106, and the other part of the input capacitor 213 is disposed between the switch units 211 and 212.

FIG. 1E shows a side cross-sectional view of a power module 1A, wherein a side cross-sectional view of the switch assembly layer 20 is shown along a broken line side of A1-O-O′-A3 as shown in FIG. 1B and FIG. 1D, and then a side cross-sectional view of A1-O and a side cross-sectional view of an O′-A3 part are unfolded to form a schematic diagram; and the side cross-sectional view of the magnetic assembly layer 10 is a schematic diagram formed along the A1-O-A2 side section shown in FIG. 1C. A side cross-sectional view of the switch assembly layer 20 and a side cross-sectional view of the magnetic assembly layer 10 are superimposed, that is, as shown in FIG. 1E.

The process flow I of the power supply module structure 1a is as follows:

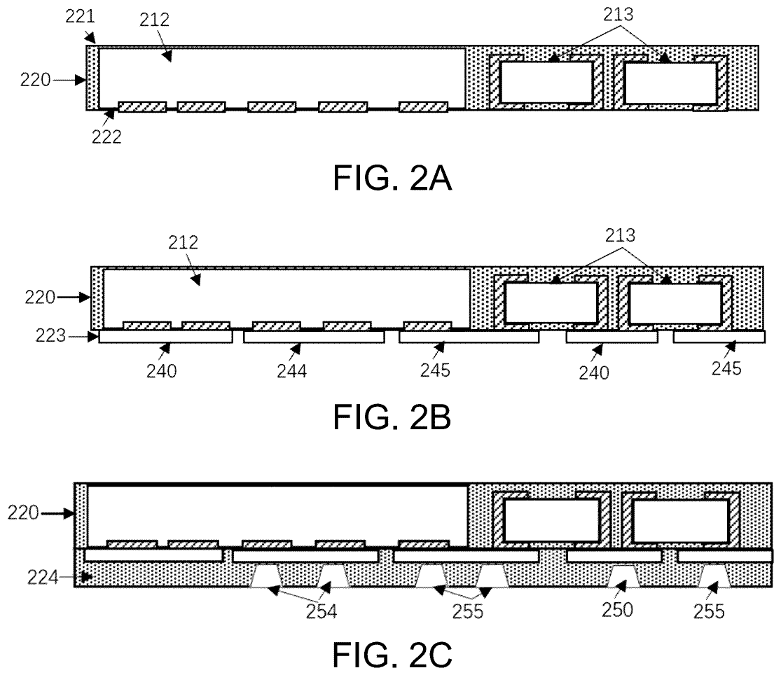

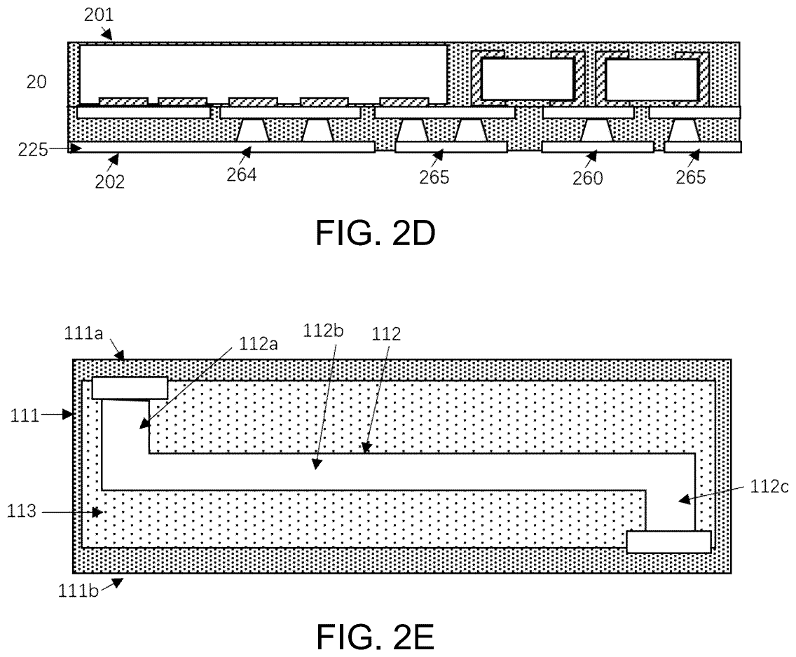

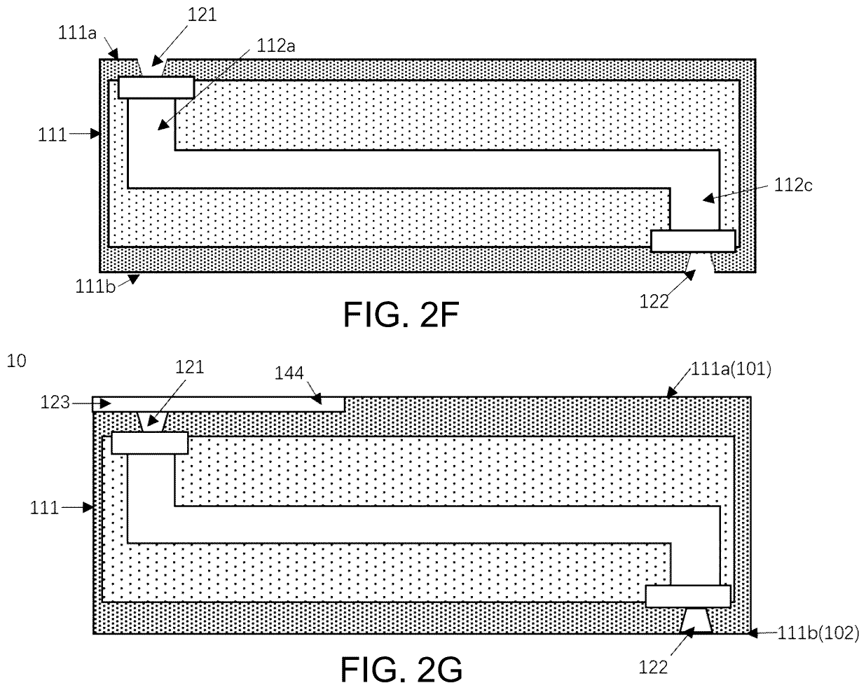

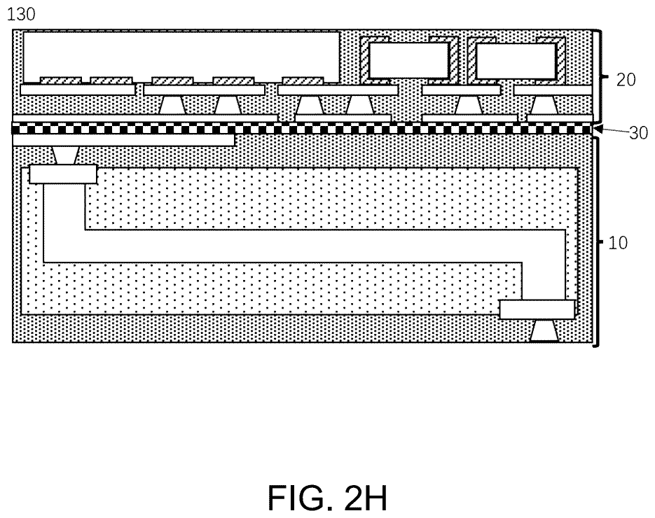

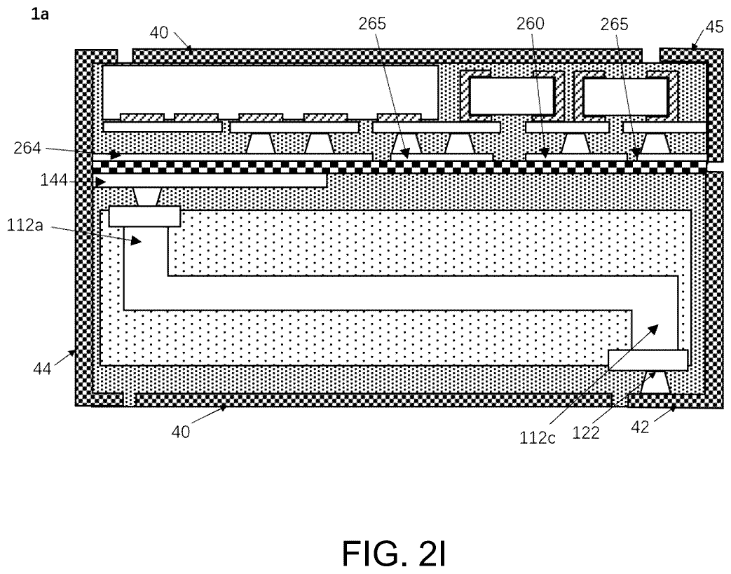

Step S1 plastic packaging: the switch units 211 and 212 and the input capacitor 213 are packaged to form a plastic package body 220, pins of the switch units 211 and 212 and pins of the input capacitor 213 are on the same plane and exposed out of the bottom surface 222 of the plastic package body 220, as shown in FIG. 2A.

Step S2, metallization: carrying out a metallization process on the bottom surface 222 of the plastic package body 220 to form a metal wiring layer 223, wherein the metal wiring layer 223 is directly connected with the pins of the switching units 211 and 212 and the pins of the input capacitor 213. As shown in FIG. 2B, the metal wiring layer 223 comprises a GND wiring layer 240, an SW2 wiring layer 244 and a Vin+wiring layer 245, the GND wiring layer is electrically connected to the GND pins of the switching units 211 and 212 and the negative electrode of the input capacitor 213, the SW2 wiring layer 244 is electrically connected to the SW1 pin of the switching unit 211, and the Vin+wiring layer 245 is electrically connected to the Vin+pin of the switching units 211 and 212 and the positive electrode of the input capacitor 213. The metal wiring layer 223 further comprises an SW1 wiring layer and other wiring layers (not shown). The SW1 wiring layer is electrically connected to the SW1 pins of the switch unit 212, and the other wiring layers may be signal wiring layers, but are not limited thereto. In other embodiments, the metal wiring layer 223 may also be electrically connected to pins of the switch units 211 and 212 and pins of the input capacitor 213 by means of via holes.

Step S3, insulating: forming an insulating dielectric layer 224 on the metal wiring layer 223 by pressing, after curing, forming an inner hole through laser drilling, as shown in FIG. 2C, the SW2 inner hole 254, the Vin+inner hole 255 and the GND inner hole 250, and further comprising an SW1 inner hole and other inner holes (not shown); the SW2 inner hole 254 is electrically connected to the SW2 wiring layer 244, the Vin+inner hole 255 is electrically connected to the Vin+wiring layer 245, the GND inner hole 250 is electrically connected to the GND wiring layer 240, and so on, and the SW1 inner hole and the other inner holes are respectively electrically connected to a corresponding wiring layer on the metal wiring layer 223.

Step S4, pin fan-out: continuing metallization on the surface of the insulating dielectric layer 224 to form a metal wiring layer 225, the metal wiring layer 225 being electrically connected to a corresponding wiring layer in the metal wiring layer 223 by means of a corresponding inner hole to form a switch assembly layer 20, as shown in FIG. 2D, the metal wiring layer 225 comprising a GND wiring layer 260, a SW2 wiring layer 264, and a Vin+wiring layer 265; and the metal wiring layer 225 further comprises a SW1 wiring layer and other wiring layers, and can be electrically connected with corresponding wiring layers in the metal wiring layer 223 through corresponding inner holes. Here, the first surface 201 and the second surface 202 of the switch assembly layer 20 are as shown in FIG. 2D.

Step S5, a magnetic piece is embedded: the inductors L1 and L2 are embedded into the circuit substrate 111. As shown in FIG. 2E, the circuit substrate 111 comprises a first surface 111a and a second surface 111b which are opposite to each other. The inductors L1 and L2 comprise a magnetic core 113, a first winding (not shown) and a second winding 112. The inductors L1 and L2 can be integrally pressed by adopting a winding and a magnetic material, and can also be formed by assembling a winding and a formed magnetic core. The second winding 112 comprises a first end 112a, a winding main body 112b and a second end 112c. The winding main body 112b extends from the first end 112a to the second end 112b in a direction parallel to the first surface 112. The first end 112a extends from the winding main body 112b to the first surface 111a of the circuit substrate 111, and the second end 112c extends from the winding main body 112b to the second surface 111b of the circuit substrate 111; the first winding also comprises a first end, a winding main body and a second end, the shape of the first winding is the same as that of the second winding, the first end extends from the winding main body to the first surface 111a of the circuit substrate 111, and the second end extends from the winding main body 112b to the second surface 111b of the circuit substrate 111.

Step S6, drilling is performed: a first surface 111a of the circuit substrate 111 is drilled at a position of the first end 112a to form an inner hole 121, and drilled at the position of the second surface 111b at the second end 112c to form an inner hole 122. As shown in FIG. 2F, a laser drilling mode can be adopted, and the inner hole can be a conical hole or a groove-shaped hole, but is not limited thereto. Similarly, a position corresponding to the first end and the second end of the first winding is also drilled to form an inner hole (not shown), and the inner hole is connected to the corresponding first end or second end.

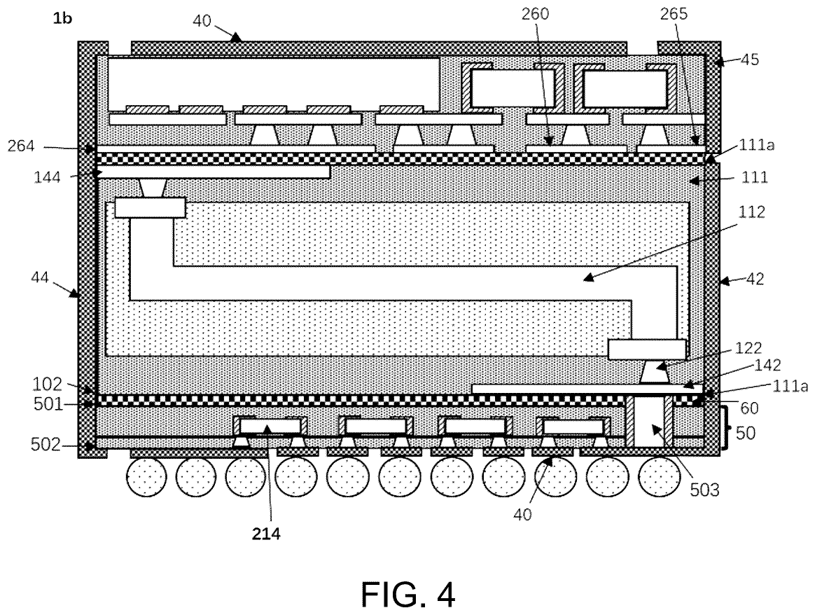

Step S7, inductor pin fan-out: performing metallization on a first surface 111a of the circuit substrate 111 to form a metal wiring layer 123, the metal wiring layer 123 being electrically connected to a first end of the winding by means of a corresponding inner hole, forming a magnetic assembly layer 10 as shown in FIG. 4, and the SW2 wiring layer 144 being electrically connected to a first end 112a of the second winding 112 by means of an inner hole 121. Here, the first surface 111a of the circuit substrate 111 is the first surface 101 of the magnetic component layer 10, and the second surface 111b of the circuit substrate 111 is the second surface 102 of the magnetic component layer 10.

Step S8: secondary insulation: a first connecting layer 30 is introduced between the second face 201 of the switch assembly layer 20 formed in the step S4 and the first face 101 of the magnetic assembly layer 10 formed in the step S7, and the switch assembly layer 20, the first connecting layer 30 and the magnetic assembly layer 10 form an assembly body 130 through a pressing process; and the first connecting layer 30 (and the connecting layer for other fixed connection mentioned later) can be made of an insulating dielectric material such as a prepreg (Pre-Preg) or ABF (Ajinomoto Build-Up Film). As shown in FIG. 2H.

Step S9, interconnection is carried out, specifically, a metal interconnection layer and a signal electrical connector are formed on the surface of the assembly body 130 through plate edge milling grooves or drilling holes, and then through a metallization process. The metal interconnection layer extends from the top surface of the power module to the bottom surface, covers part of the top surface, part of the side surface and part of the bottom surface, and is electrically connected with the corresponding wiring layer in the assembly body 130. Referring to FIG. 1B and FIG. 1C, the metal interconnection layer comprises a GND interconnection layer 40, a Vo1+interconnection layer 41, a Vo2+interconnection layer 42, an SW1 interconnection layer 43, an SW2 interconnection layer 44, and a Vin+interconnection layer 45. As shown in FIG. 21, the SW2 interconnection layer 44 is electrically connected to the SW2 wiring layers 264 and 144, so that the SW pin of the switch unit 111 is electrically connected to the second winding 112 by means of the SW2 wiring layer and the SW2 interconnection layer; the Vin+interconnection layer 45 is electrically connected with the Vin+wiring layer 265; the GND interconnection layer 40 is electrically connected with the GND wiring layer 260; and the inner hole 122 is electrically connected with the Vo2+interconnection layer 42. In the embodiment, the other wiring layers in the metal wiring layers 223, 225 and 123 can be electrically connected with the corresponding interconnection layers, so that the power electric energy and the control signals can transmit between the switch assembly layer and the system board. The signal connection piece 46 is disposed on the side surface 106 of the power supply module 1a, extends from the top surface of the power supply module 1a to the bottom surface, covers a part of the side surface, and is electrically connected to the metal wiring layer in the power supply module 1a, thereby realizing signal transmission between the system board and the power supply module.

In the power supply module 1a and the process flow I disclosed in Embodiment 1, no traditional welding point exists in the power supply module 1a, the switch assembly layer 20 and the magnetic assembly layer 10 are integrally pressed through an insulating material, the switch unit and the input capacitor both directly grow a metal wiring layer from the positions of the pins, the inductors L1 and L2 directly grow a metal wiring layer from the pin position, and the two metal wiring layers are fixedly connected through the first connecting layer 30. Therefore, in the embodiment, the welding layer which is used for fixing and electrically connecting the switch assembly layer 20 and the magnetic assembly layer 10 is not included in the embodiment. When the bottom surface of the power supply module 1a is welded with the system board, the welding high temperature does not cause remelting of welding spots or welding layers in the power supply module 1a, and a series of failure problems caused by remelting of welding spots in the power supply module 1a cannot be caused, and the failure problems comprise device displacement or cracks generated at the welding layer position and the like. In addition, as the power of the module becomes higher and higher, when the power supply module operates, the temperature generated by the internal device is increased, the temperature can reach 125-150° C., and the melting point of the solder is about 220° C., so that the reliability of the strength of the welding spot is reduced due to the internal temperature rise; and in the embodiment, the cross-layer electric interconnection structure is formed directly on the side surface of the module, internal welding spots are not needed, and the reliability of the cross-layer electric interconnection structure in the high-temperature working environment is also improved.

In addition, the metal interconnection layer extends from the top surface of the power supply module to the bottom surface of the power supply module through the side surface, and the metal interconnection layer is directly connected with the substrate layer of the switch unit through the metal wiring layer. Due to the fact that the loss proportion of the switch unit in the whole power supply module is large, the metal wiring layer directly and rapidly transmits the heat of the switch unit to the metal interconnection layer, the area of the metal interconnection layer is larger than the area of the switch unit, the heat conductivity in the horizontal direction is high, the heat flow area of the switch unit is effectively increased, and the thermal resistance in the vertical direction of the power supply module is reduced. In the embodiment, the thickness of the metal interconnection layer is greater than 200 μm, so that the upward thermal resistance of the power supply module can be further reduced. According to the power supply module formed by the process flow I, the production efficiency can be improved through parallel production; and through the integrated pressing and forming and metal interconnection layer process, the flatness of the bottom surface of the power supply module is good, and the yield of welding with the system board is improved.

### Embodiment 2

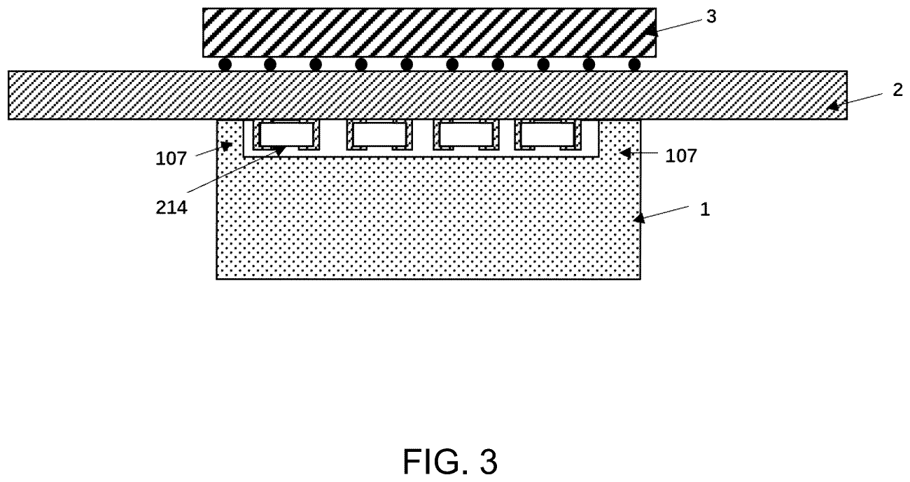

As the demand of the load on the power supply power becomes larger and larger, the dynamic requirement for the power supply is higher and higher; at present, a vertical power supply mode is mostly adopted, as shown in FIG. 3, the power supply module 1 and the load 3 are arranged on the two opposite sides of the system board 2 respectively, so that the distance between the power supply module and the load is shorter, and the influence of parasitic parameters on the transmission path on the dynamic response performance is reduced. Meanwhile, the power supply module 1 comprises two high-leg structures 107, and the high-leg structures 107 are used for transmitting energy and signals between the system board and the power supply module; and a cavity is formed between the two high-leg structures 107 and is used for arranging an output capacitor 214, so that the output capacitor 214 is arranged between the power supply module 1 and the system board 2, and the dynamic performance requirement of the load on the power supply module is met. But energy and signals are both arranged in the two high-leg structures 107, so that the wiring is crowded, and the flexibility of wiring is reduced; and furthermore, the current-carrying capacity of the power supply module is limited, and the transmission impedance from the power supply module to the load is increased.

In order to solve the above problems, the invention discloses a power supply module 1b in Embodiment 2. On the basis of the power supply module 1a shown in Embodiment 1, an output capacitor layer 50 is integrated and is arranged adjacent to a second surface 102 of the magnetic assembly layer 10, as shown in FIG. 4. A second connecting layer 60 is arranged between the second surface 102 of the magnetic component layer 10 and the first surface 501 of the output capacitor layer 50, and a metal wiring layer is arranged on the second surface 102 of the magnetic component layer 10 and electrically connected with the second ends of the first winding and the second winding respectively. As shown in FIG. 4, the Vo2+wiring layer 142 is electrically connected with the inner hole 122. The metal interconnection layer extends from the first surface 201 of the switch component layer 20 to the side surface of the power supply module, and then extends to the second surface 502 of the output capacitor layer 50 to output the capacitor pin fan-out and is electrically connected with the pin fan-out of the magnetic component layer 10 through the metal interconnection layer. The output capacitor layer 50 further comprises a blind hole 503, but is not limited to a blind hole or a blind groove.

The detailed steps of the process flow II of the power supply module structure 1b are as follows:

Step S1a to step S6a of the process flow II are the same as steps S1 to S6 of the process flow I;

Step S7a: an inductor pin fan-out: and metallizing the first surface 111a and the second surface 111b of the circuit substrate 111 to form a metal wiring layer, the metal wiring layer is electrically connected with the first end or the second end of the winding through the corresponding inner holes, the magnetic assembly layer 10 is formed. As shown in FIG. 4, the SW2 wiring layer 144 is electrically connected with the first end 112a of the second winding 112 through the inner hole 121, and the Vo2+wiring layer 142 is electrically connected with the second end 112b of the second winding 112 through the inner hole 122. Here, the first surface 111a of the circuit substrate 111 is the first surface 101 of the magnetic component layer 10, and the second surface 111b of the circuit substrate 111 is the second surface 102 of the magnetic component layer 10.

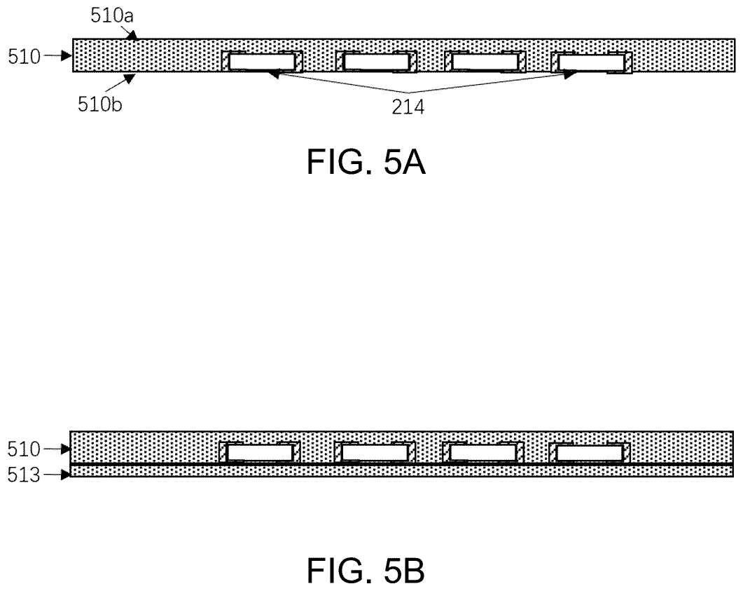

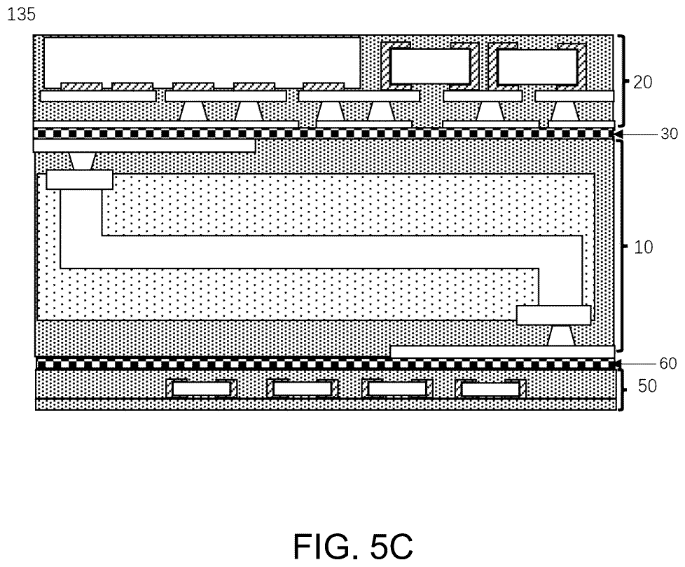

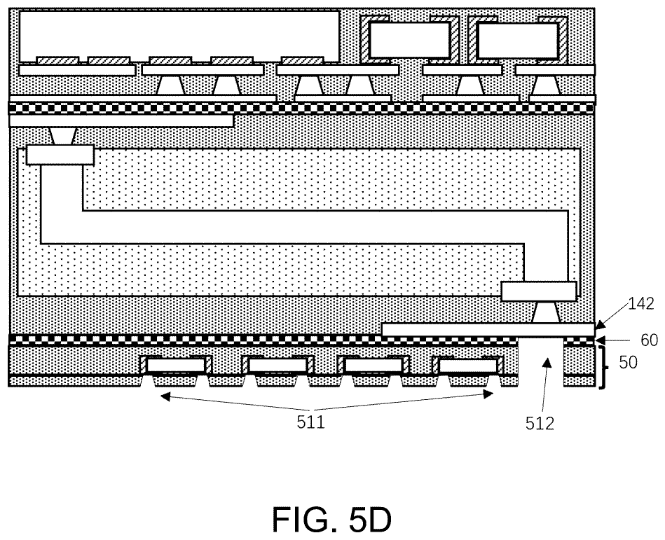

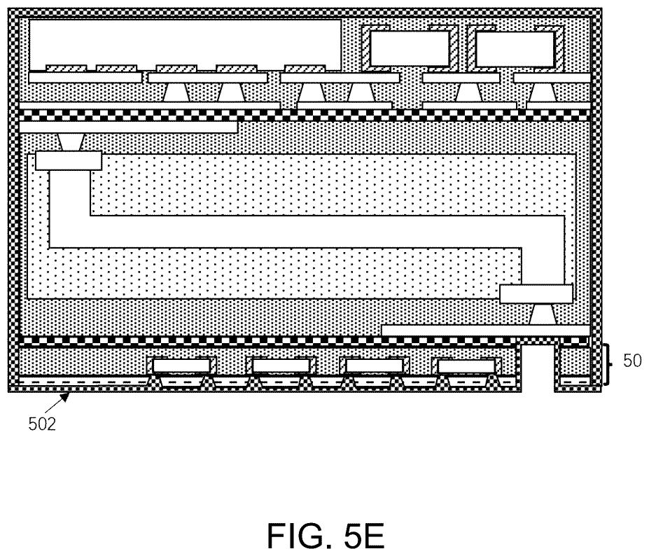

Step S8a: laminating an output capacitor: forming a plastic package body 510 by plastic packaging on an output capacitor 214, wherein the plastic package body 510 comprises a first surface 510a and a second surface 510b which are opposite to each other, and pins of the output capacitor 214 are exposed out of the second surface 510b, as shown in FIG. 5A; and then laminating to form a insulating dielectric layer 513 on the second surface 510b of the plastic package body 510, as shown in FIG. 5B. In other embodiments, the output capacitor 214 may also be embedded in the circuit substrate.

Step S9a, secondary insulation: introducing a first connecting layer 30 between the second surface 201 of the switch assembly layer 20 formed in the step S4a and the first surface 101 of the magnetic assembly layer 10 formed in the step S7a; a second connecting layer 60 is introduced between the second face 102 of the magnetic assembly layer 10 formed in the step S7a and the first face 501 of the output capacitor layer 50 formed in the step S8a. The switch assembly layer 20, the first connecting layer 30, the magnetic assembly layer 10, the second connecting layer 60 and the output capacitor layer 50 are laminated into an assembly body 135 through a pressing process as shown in FIG. 2H. In other embodiments, the switch assembly layer 20, the first connecting layer 30 and the magnetic assembly layer 10 can also be pressed first, and then are laminated with the second connection layer 60 and the output capacitor layer 50.

Step S10a: drilling and electroplating: drilling at the pin position of an output capacitor 214 from a second surface 502 of an output capacitor layer 50 to form a hole groove 511, and forming a hole groove 511 in a laser drilling mode; and drilling a hole at the second end of the winding or the position of the grounding end of the power supply module to form a hole groove 512, the hole groove 512 penetrates through the output capacitor layer 50 and is connected with the Vo2+wiring layer 142, as shown in FIG. 5D, the hole groove 512 can be formed by adopting a laser grooving or mechanical milling groove mode. The hole groove 511 is filled with a metal material through a metal process, the hole groove 512 is electroplated, then the second surface 502 of the output capacitor layer 50 shown in FIG. 5E is formed through surface plating, etching and other processes, and the hole groove can be a circular hole, a square hole, a rectangular hole and an irregular hole.

Step S11a, interconnection: a metal interconnection layer is formed on the surface of the assembly body 135 through a plate edge milling groove or a drilling hole, and then a metal interconnection layer is formed through a metallization process. The metal interconnection layer extends from the top surface of the power supply module 1b to the bottom surface, covers part of the top surface, part of the side surface and part of the bottom surface, and is electrically connected with a corresponding wiring layer in the assembly body 135. As shown in FIG. 4, the metal interconnection layer comprises a GND interconnection layer 40, a Vo1+interconnection layer 41, a Vo2+interconnection layer 42, an SW1 interconnection layer 43, an SW2 interconnection layer 44 and a Vin+interconnection layer 45 SW2, and the interconnection layer 44 is electrically connected with the SW2 wiring layers 264 and 144, so that the SW pin of the switch unit 111 is electrically connected with the second winding 112 through the SW2 wiring layer and the SW2 interconnection layer; the Vin+interconnection layer 45 is electrically connected with the Vin+wiring layer 265; the GND interconnection layer 40 is electrically connected with the GND wiring layer 260; and the Vo2+wiring layer 142 is electrically connected with the Vo2+interconnection layer 42. In the embodiment, other wiring layers in the metal wiring layer can be electrically connected with the corresponding interconnection layer, so that the power electric energy and the control signal can transmit between the switch assembly layer and the system board.

The power supply module 1b disclosed by the embodiment can also adopt a multi-layer output capacitor layer which is stacked on the second surface 102 of the magnetic assembly layer 10, and is electrically connected with the metal interconnection layer through the capacitor pin fan-out; the problem that the placement position and the number of the output capacitors are limited is solved, the area of each bonding pad on the bottom surface of the power supply module is expanded through the metal interconnection layer, and the problems encountered in the prior art in FIG. 3 are solved.

### Embodiment 3

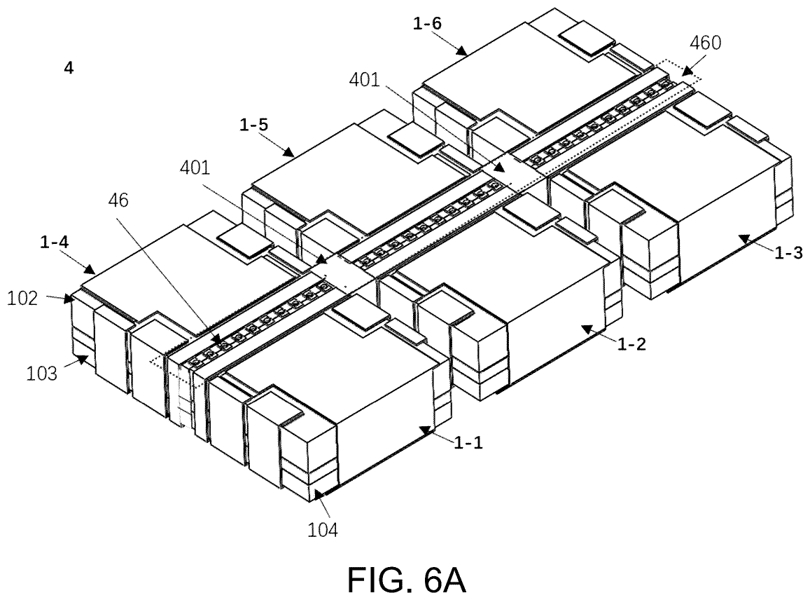

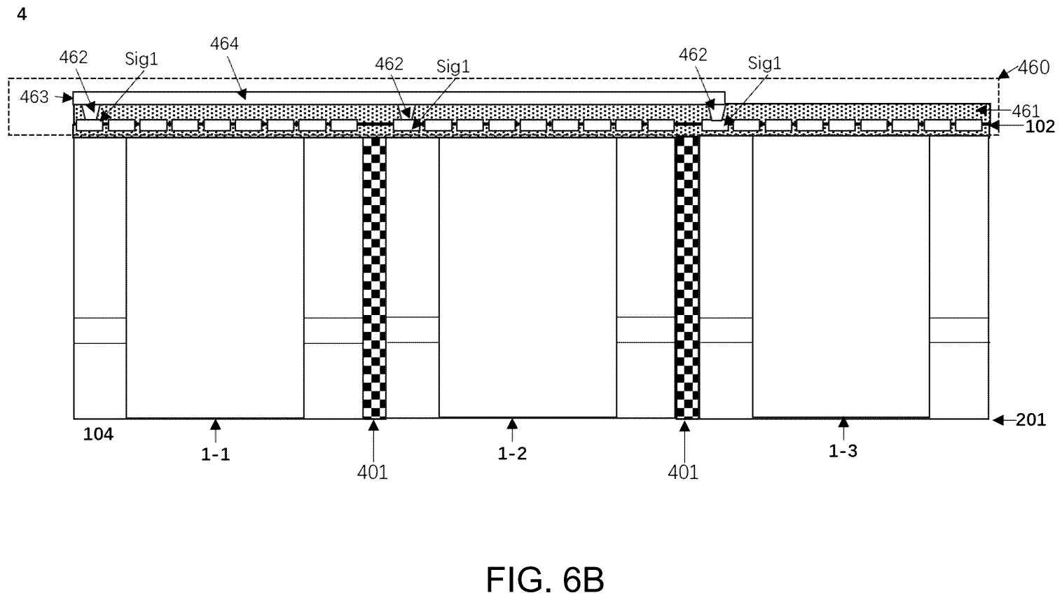

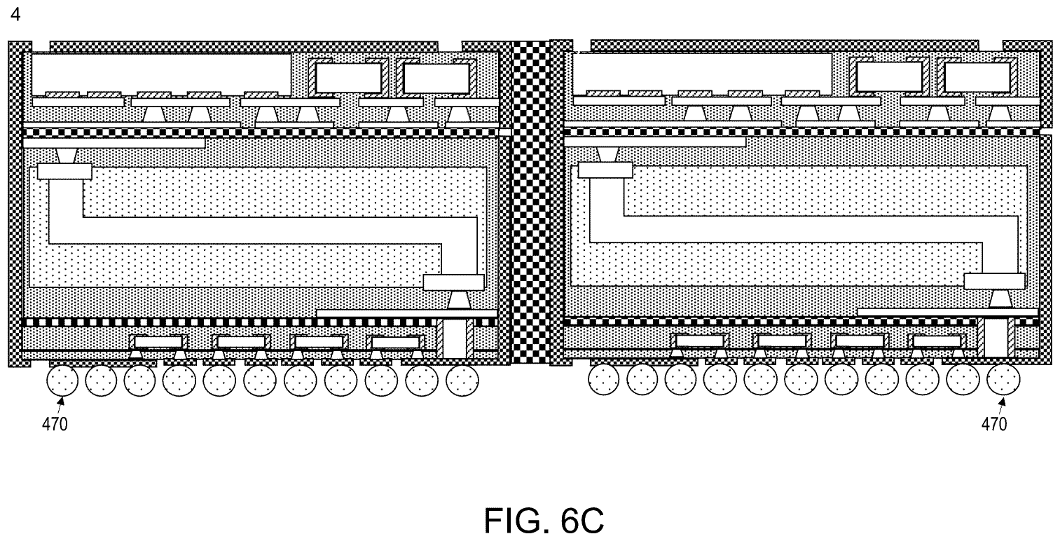

In order to solve the requirement of load on large-current power supply, the current required by the load can reach about 1000A, and the power supply current of each power supply module is about 80A Therefore, the embodiment adopts a plurality of power supply modules to be connected in parallel. One application mode is to respectively weld a plurality of discrete power supply modules on the bottom surface of a system board; the other application mode is to integrate a plurality of power supply modules in an integrated module, and as shown in FIG. 6A, the six power supply modules 1 are integrated in one integrated module 4 as an example for description, but are not limited thereto. Side surfaces 106 of every two power supply modules 1 (such as power supply modules 1-1 and 1-4) are adjacently arranged to form a group of power supply modules, and the two adjacent power supply modules 1 share one group of signal electrical connectors 46; holes can also be drilled between a group of power supply modules, required signal electrical connectors 46 are formed through electroplating, and signals of each power supply module in one group of power supply modules are electrically connected with the corresponding signal electrical connectors. The two adjacent power supply modules are connected through the connection position 401, and the connection position 401 extends from the top surface 201 of the power supply module to the bottom surface 102 and can be formed by pressing an insulating material.

In the present embodiment, one power module 1 comprises nine signal electrical connectors (such as a signal electrical connector Sig1), and one integrated module 4 comprises six power modules 1-1 to 1-6, ie comprising 27 signal electrical connectors. When the integrated module 4 is fixedly and electrically connected with the system board, corresponding 27 signal bonding pads need to be arranged on the system board, and the wiring complexity in the system board is increased. In order to reduce the wiring complexity of the system board, in the signal area 460 on the bottom surface 102 of the power supply module shown in FIG. 6A, the insulating dielectric layer 461 is pressed again and electroplated, as shown in the inner hole 462 in FIG. 6B, the inner hole 462 is electrically connected with each signal electric connector Sig1, and then the surface of the insulating dielectric layer 461 is metalized to form the metallized wiring layer 463, so that the signal wiring layer 464 is electrically connected with each inner hole 462. Therefore, the wires corresponding to the signal electrical connectors Sig1 on the system board are gathered together and are electrically connected with the signal wiring layer 464. As shown in FIG. 6B, only the signal electrical connector Sig1 is taken as an example for description. Similarly, the other eight signal electrical connectors in each power supply module 1 can be electrically connected to the corresponding signal wiring layers by means of corresponding inner holes, thereby reducing the wiring complexity on the system board.

Furthermore, the bottom surface of the integrated module 4 can be completely laminated with one insulating dielectric layer, then drill and electroplate in the area of the metal interconnection layer on the bottom surface, and the corresponding metal wiring layer is formed through metallization, so that the gathering of the power pin routing is realized, and the wiring complexity on the system board is further reduced.

In the embodiment, because the integrated module 4 is integrally welded to the system board, the problem of flatness of the bottom surface of the integrated module 4 is solved, the welding difficulty with the system board is increased, and the power supply reliability is reduced. As shown in the side cross-sectional view shown in FIG. 6C, each welding ball in the ball grid array package (BGA) is electrically connected with the corresponding interconnection layer on the bottom surface of each power supply module 1, and is used for absorbing the tolerance of the flatness of the bottom surface of the integrated module 4. Furthermore, the welding ball 470 at the edge of the bottom surface of the integrated module 4 is a copper alloy ball coated with a tin layer, and at least four welding ball 470 are arranged in one integrated module and are respectively located at four corners of the integrated module. When the integrated module and the system board are assembled, firstly, the integrated module and the system board are mechanically locked, and then reflow soldering is carried out. Due to the fact that the welding ball 470 is arranged on the edge of the integrated module, when other welding balls are melted at high temperature, the whole integrated module is supported by the welding ball 470, welding collapse caused by overlarge or overweight of the integrated module is avoided, and the assembly failure efficiency is reduced.

### Embodiment 4

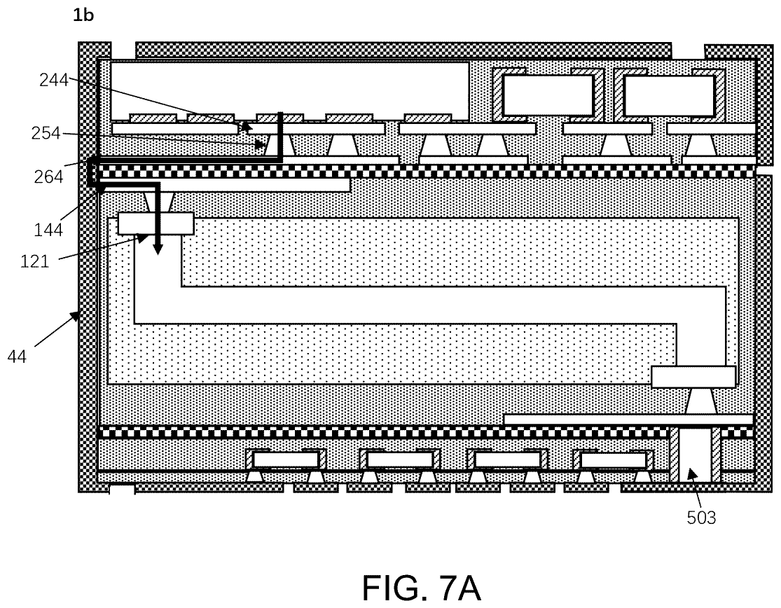

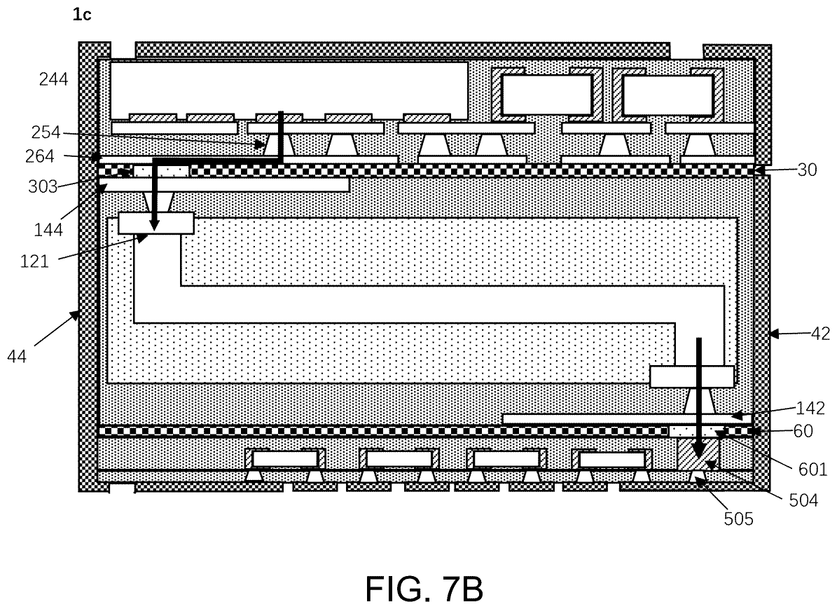

In the power module structure shown in the above embodiment, the metal wiring layer with the same potential is connected through the metal interconnection layer, as shown in FIG. 7A, the current flows from the SW pin of the switch unit 212 and flows into the first end 112a of the second winding 112 through the SW2 wiring layer 244, the SW2 inner hole 254, the SW2 wiring layer 264, the part of the SW interconnection layer 44, the SW2 wiring layer 144 and the inner hole 121, and the current flows into the first end 112a of the second winding 112. It's obviously that the path of the current flowing is long, and the parasitic resistance of the path is large, and the conversion power of the power supply module is increased.

On the basis of the power supply module 1b shown in FIG. 4, the first bonding layer 303 is added to the first connecting layer 30, as shown in FIG. 7B. The first bonding layer 303 is connected with the SW2 wiring layers 264 and 144, and the material for forming the first bonding layer comprises brazing filler metal, tin-silver alloy, tin-copper alloy, tin-silver-copper alloy, tin-antimony alloy, gold-tin alloy, high-lead solder, silver sintering slurry, copper sintering slurry, instantaneous liquid-phase sintering material or conductive slurry. By adding the first bonding layer, the current path from the switch unit to the winding not only comprises a metal interconnection layer path, but also a metal bonding layer path, the two paths are connected in parallel, and the equivalent transmission impedance on the current transmission path is reduced. Moreover, the melting point of the bonding layer material is as high as hundreds of degrees or even thousands of degrees (such as silver sintering, the melting point temperature is greater than 800° C.), the melting point of the client solder is about 220° C., the maximum welding temperature is about 245° C., and the highest welding temperature is far lower than the melting point of the bonding material in the power supply module, so that when the power supply module is welded to the system plate, remelting of the bonding layer in the power supply module is not caused, and the reliability of power supply is improved while the equivalent transmission impedance is reduced.

Furthermore, the second connection layer 60 may also include a second bonding layer 601, as shown in FIG. 7B. Together with the copper column 504 and the inner hole 505 are used for connecting the Vo2+wiring layer 142 and the Vo2+interconnection layer. The second bonding layer 601 is connected with the second end 112a of the second winding 112, the position of the copper column 504 is close to the second bonding layer 601, and the inner hole 505 is connected with the copper column 504 and the Vo2+interconnection layer 42, so that the current path flowing out of the second winding 112 not only comprises a metal interconnection layer, but also the path of the second bonding layer, the copper column and the inner hole, and the transmission impedance of the copper column is far smaller than the transmission impedance of the inner hole. The two current paths are connected in parallel, so that the transmission impedance on the current path can be reduced.

Specifically, the process flow 3 of the power supply module 1c shown in FIG. 7B is as follows:

Step S1b to step S7b are the same as steps S1a to S7a of the process flow II, wherein with steps S1b to S4b, a switch assembly layer 20 is formed, and with steps S5b to S7b, a magnetic assembly 10 is formed.

Step S8b, pressing the output capacitor: the output capacitor 214 and the copper column 504 are subjected to plastic packaging to form a plastic package body 510, the plastic package body 510 comprises a first surface 510a and a second surface 510b which are opposite, the pins of the output capacitor 214 are exposed out of the second surface 510b, the upper end surface of the copper column 504 is exposed to the first surface 510a through a brush plate process, and the lower end surface of the copper column 504 is exposed out of the second surface 510b.

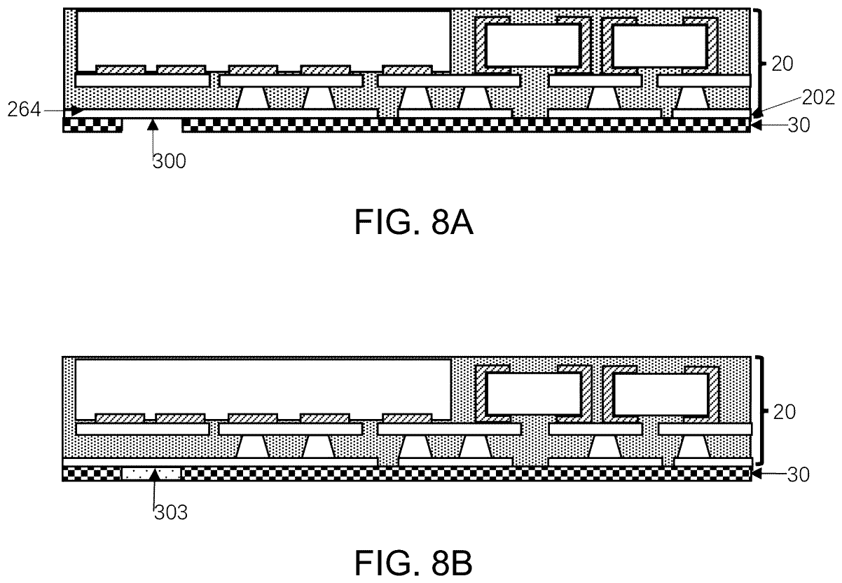

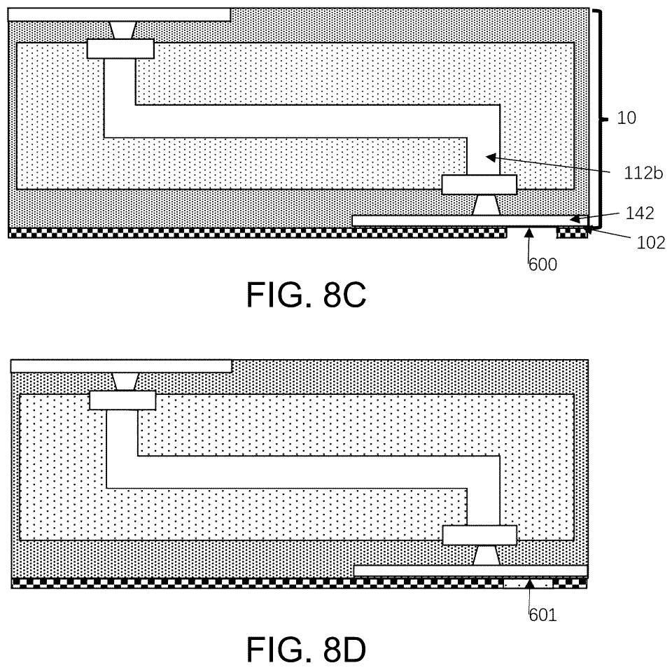

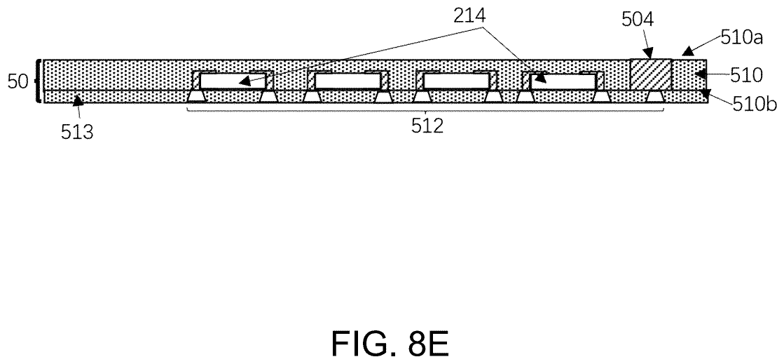

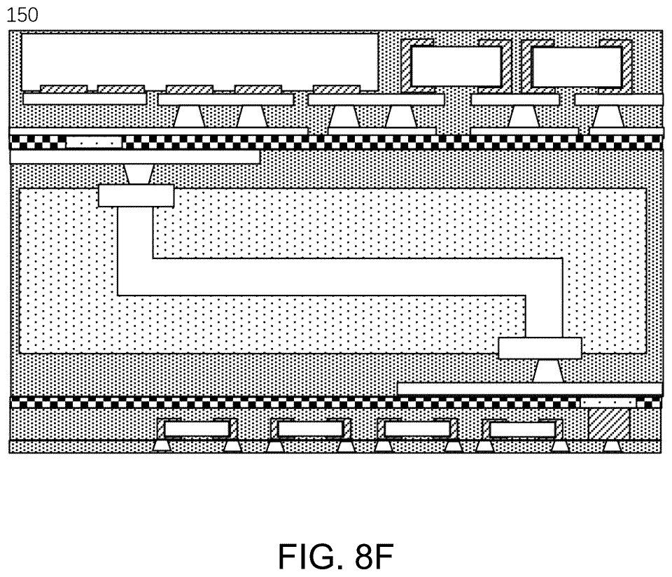

Then, an insulating dielectric layer 513 is laminated on the second surface 510b of the plastic package 510, and a hole is drilled in the insulating dielectric layer 513 to form a plurality of inner holes 512 to form the output capacitor layer 50 as shown in FIG. 8E In other embodiments, the output capacitor 214 and the copper column 504 can also be embedded in the circuit substrate.

Step S9b secondary insulation: laminating and semi-curing the insulating material and the switch assembly layer 20 and semi-curing, forming a first connecting layer 30 on the second surface 202 of the switch assembly layer 20, as shown in FIG. 8A, and making the window 300 on the first connecting layer 30 adjacent to the SW2 wiring layer 264, but not limited thereto.

Step S10b, three-time insulation: laminating and semi-curing the insulating material and the magnetic component layer 10, and semi-curing, forming a second connecting layer 60 on the second surface 102 of the magnetic component layer 10, as shown in FIG. 8C, and making the window 600 on the second connecting layer 60 adjacent to the second end 112b of the second winding 112. A laser windowing mode can be adopted, but is not limited thereto. Step S11b bonding: respectively implanting a bonding material into the window 300 and the window 600 to form a first bonding layer 303 and a second bonding layer 302, as shown in FIG. 8B and FIG. 8D.

The first bonding layer 303 is connected to the SW2 wiring layer 264, and the second bonding layer 601 is connected to the Vo2+wiring layer.

Step S12b, baking: removing a solvent, such as glycerol, ethylene glycol, etc., from the switch assembly layer and the magnetic assembly layer formed in S11b, integrally pressing with an output capacitor layer formed by S8b, and continuously baking and pressurizing the semi-cured first connecting layer 30 and the second connection layer 60, so that the two parts of the two sides of the first bonding layer and the second bonding layer form an assembly body 150, as shown in FIG. 8F.

Step S13b interconnection: forming a metal interconnection layer on the surface of the assembly body 150 through a plate edge milling groove or a drilling hole, and then forming a metal interconnection layer through a metallization process, wherein the metal interconnection layer extends from the top surface of the power supply module 1c to the bottom surface, covers part of the top surface, part of the side surface and part of the bottom surface, and is electrically connected with the corresponding wiring layer in the assembly body 150. Referring to FIG. 7B and step S11a, the metal interconnection layer has the same technical features and advantages as step S11a, and details are not described herein again.

In the embodiment, the number of the first bonding layers and the number of the second bonding layers are not limited to one as shown in FIG. 7B, a plurality of first bonding layers can be arranged in the first connecting layer 30, a plurality of second bonding layers are arranged in the second connecting layer 60, electrical connection of the corresponding wiring layers is achieved, and the transmission impedance on the current transmission path is reduced.

The structure and process of the bonding layer disclosed by the embodiment are also suitable for the power supply module 1a, and the same technical features and advantages shown by the power supply module 1c can also be obtained.

### Embodiment 5

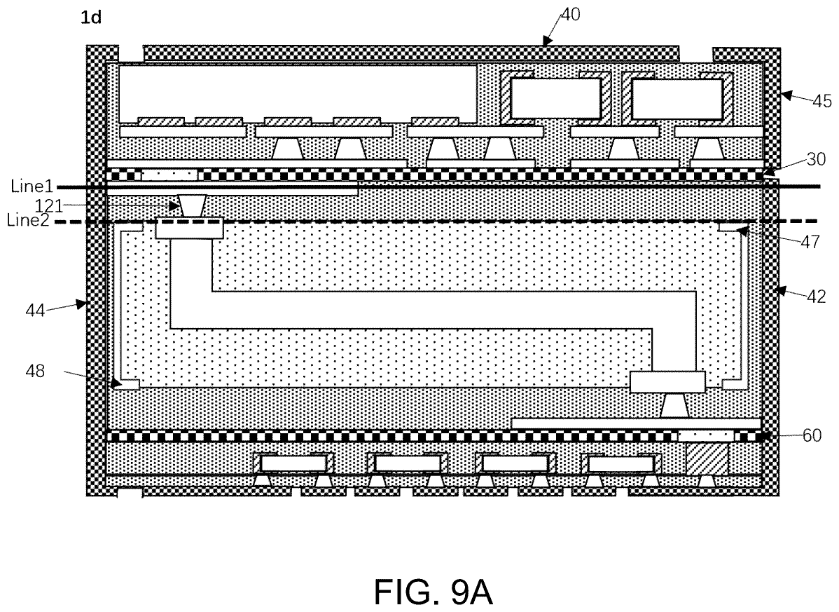

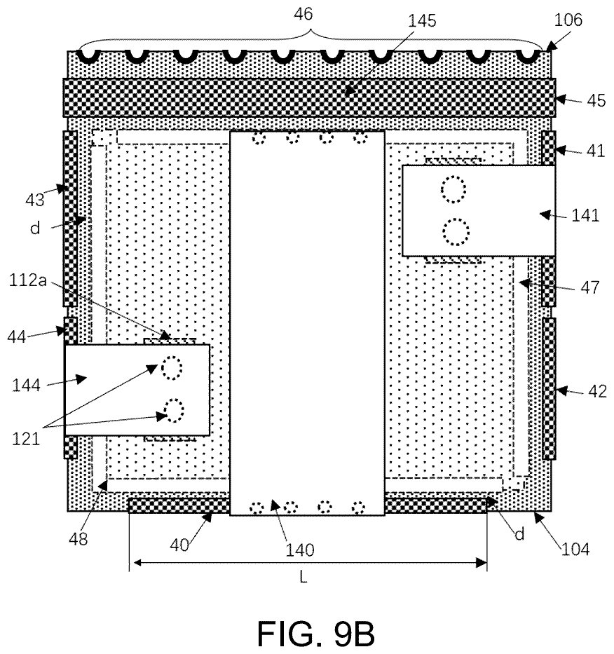

In this embodiment, in order to further reduce the parasitic parameters of the power supply module, and improve the conversion efficiency of the power supply module, copper foils 47 and 48 are wrapped on the outer sides of the inductors L1 and L2, as shown in FIGS. 9A and 9B, the solid line part in FIG. 9B is the part displayed along the cross section in the linear Line1 direction in FIG. 9A, and the dotted line part of FIG. 9B is the part displayed along the cross section in the linear Line2 direction in FIG. 9A. The copper foil 47 and the copper foil 48 cover part of the top surface, part of the side surface and part of the bottom surface of the inductors L1 and L2. The copper foils 47 and 48 may cover 50%-99% of the total area of the four side surfaces of the inductors L1 and L2, but are not limited thereto. As shown in FIG. 9B, the SW2 wiring layer 144 is electrically connected to the end surface of the first end 112a of the second winding 112 by means of the inner hole 121, and the SW2 wiring layer 144 extends to the SW2 interconnection layer 44 on the side surface of the power supply module 1d and is electrically connected to the SW2 interconnection layer 44. Similarly, the SW1 wiring layer 143 is also electrically connected to the first end surface of the first winding by means of the inner hole, and the SW1 wiring layer 143 extends to the SW1 interconnection layer 43 on the side surface of the power supply module 1d and is electrically connected to the SW1 interconnection layer 43.

Similarly, the GND wiring layer 140 is electrically connected with the copper foil 47 through the inner hole, and the GND wiring layer 140 extends to the GND interconnection layer on the side surface of the power supply module Id and is electrically connected with the GND interconnection layer 40. The copper foil 47 is arranged between the SW1 potential and the SW2 potential and the signal interconnection layer 46, and the copper foil 47 can play an electromagnetic shielding effect, so that the signal on the signal interconnection layer 46 is not influenced by the jump potential SW1 and SW2. The SW1/SW2 potential here includes a first end surface of the winding, an SW1/SW2 interconnection layer, and an SW1/2 wiring layer. Furthermore, the copper foil 48 is electrically connected to the Vin+interconnect layer 45. On one side of the side surface 104 of the power supply module 1d, the distance between the copper foil 48 and the GND interconnection layer is d, and the length of the GND interconnection layer in the horizontal direction is L, as shown in FIG. 9b. The cross-sectional area S of the overlapping area between the copper foil 48 and the GND interconnection layer is S=L*d. Because the numerical value of the distance d is small, for example, d<0.2 mm, the parasitic inductance of the overlapping area part is correspondingly small. By means of the arrangement, overlapping arrangement of the input positive wire and the grounding wire is achieved, the distance after overlapping is d, and the smaller the distance d, the smaller the loop area surrounded by the input wire and the grounding wire, the smaller the parasitic inductance is. The reduction of the parasitic inductance can effectively inhibit the voltage peak, avoid the failure of the switch unit caused by overvoltage, effectively reduce the switching loss of the switch unit, and improve the voltage conversion efficiency of the power supply module. Furthermore, on the second surface 102 of the magnetic assembly 10, the wiring layer is electrically connected to the corresponding interconnection layer in the same manner. The implementations of the inductor L1 and the L2 integrated copper foil 47 and the copper foil 48 can be electroplated to form a copper foil after assembly and plastic packaging, or directly formed by directly electroplating on the body of the inductors L1 and L2, and the implementation mode of the integrated copper foil is flexible and is not limited thereto.

### Embodiment 6

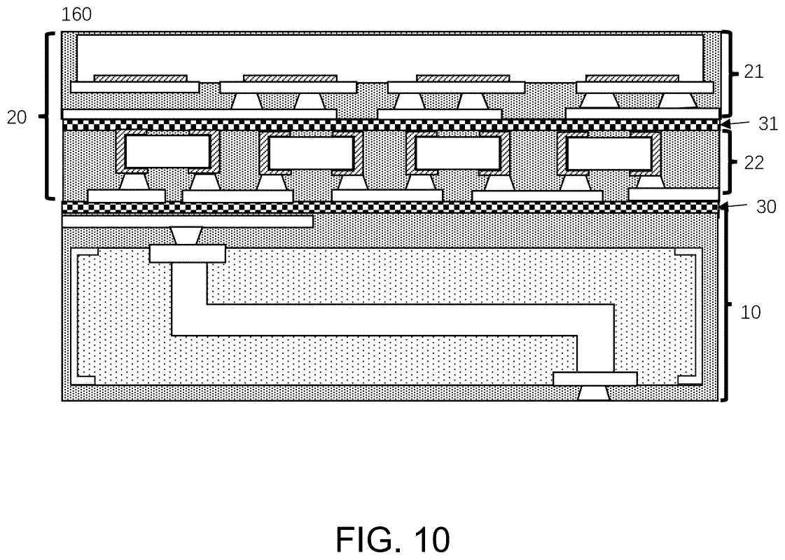

In order to reduce the cross-sectional area of the power supply module, that is, the area occupied by the power supply module on the system board is reduced, the embodiment adopts a novel structure, as shown in FIG. 10, the switch units 211 and 212, the input capacitor 213 and the inductors L1 and L2 are stacked in the vertical direction, the switch units 211 and 212 form the switch unit layer 21 according to the steps of forming the switch assembly layer 20 in the above embodiment, the input capacitor 214 used to form the input capacitor layer 22 according to the step of forming the output capacitor layer 50 in the above embodiment, and the magnetic assembly layer 10 can adopt any one of the above embodiments. The first connecting layer 30 is used for connecting the input capacitor layer 22 and the magnetic assembly layer 10, the input capacitor connection layer 31 is used for connecting the switch unit layer 21 and the input capacitor layer 22. The switch unit layer 21, the first connecting layer 30, the input capacitor layer 22, the input capacitor connection layer 31 and the magnetic assembly layer 10 are integrally pressed to form an assembly body 160; or by means of distributed lamination, the input capacitor layer 22, the switch unit layer 21 and the input capacitor connecting layer 31 are pressed into the switch assembly layer 20, then the switch assembly layer 20 and the magnetic assembly layer 10 are pressed into the assembly body 160. Then metallization is carried out on the surface of the assembly body 160 to form a metal interconnection layer, pins of the switch units 211 and 212 are electrically connected with the corresponding metal interconnection layers of the side edges through inner holes and wiring layers, pins of the input capacitor 214 are electrically connected with the metal interconnection layers corresponding to the side edges through the corresponding inner holes and the wiring layers. Similarly pins of magnetic component layer are also electrically connected with the metal interconnection layers corresponding to the side edges through the corresponding inner holes and the corresponding wiring layers. In the power supply module disclosed by the embodiment, the assembly body 160 can further comprise an output capacitor layer, and the structure and the process flow of the output capacitor layer can refer to step S8a in the process flow II.

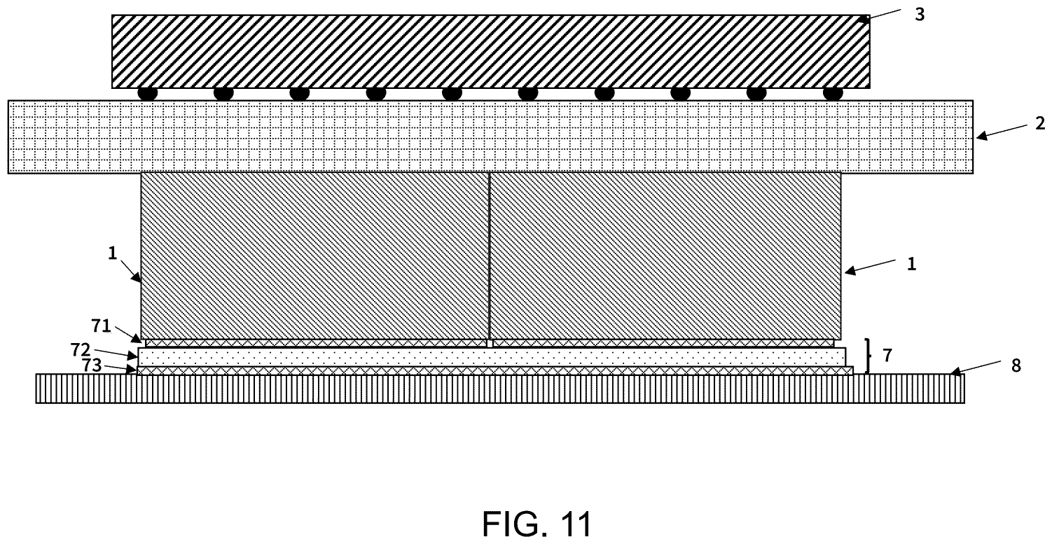

The power supply module shown in the embodiment can be suitable for a vertical power supply structure as shown in FIG. 11, and the load 3 is arranged on the top surface of the main board 2. The power supply module 1 is arranged on the bottom surface of the main board 2, a plurality of power supply modules 1 can be arranged to supply power to the load 3, and the integrated module 4 can also be arranged to improve the power supply capability; and the bottom surface of the power supply module is fixedly connected with the bottom surface of the system board. The metal interconnection layer at the top of the power supply module 1 or the integrated module 4 is connected to the vapor chamber 72 through the first heat conduction interface layer 71, so that heat generated by the switch unit in the power supply module is quickly transmitted to the vapor chamber 72. Because the vapor chamber covers the plurality of power supply modules 1 through the first heat conduction interface layer 71, so that heat generated by the switch units of the plurality of power supply modules 1 is better averaged on the vapor chamber 72. The vapor chamber 72 is connected to the housing 8 by means of a second thermally conductive interface layer 73, so that heat on the vapor chamber 72 escapes through the housing 8 more quickly. The vertical power supply structure reduces the thermal resistance in the vertical direction, further reduces the working temperature in the power supply module, and reduces the failure of the device in the power supply module due to high temperature. Here, the first heat conduction interface layer 71, the vapor chamber 72 and the second heat conduction interface layer 73 are collectively referred to as a heat dissipation assembly 7.

The switch disclosed by the application can be a Si MOSFET, SiC MOSFET, GaN MOSFET or IGBT MOSFET and etc, and the function of the switch disclosed by the application can be realized.

The power conversion device can be part of the electronic device or an independent power supply module as long as the technical features and advantages disclosed by the application can be satisfied.

The “equal” or “same” or “equal to” disclosed by the application needs to consider the parameter distribution of engineering, and the error distribution is within +/−30%; the two line segments or the two straight lines are defined as the two line segments or the included angle between the two line segments or the two straight lines is less than or equal to 45 degrees; the included angle between the two line segments or the two straight lines is within the range of [60, 120]; and the definition of the phase error phase also needs to consider the parameter distribution of the project, and the error distribution of the phase error degree is within +/−30%.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power supply module with high heat dissipation capability and high reliability, wherein the power supply module is characterized by comprising a switch assembly layer, a magnetic assembly layer, a first connecting layer and a metal interconnection layer;
the first connecting layer is arranged between the switch assembly layer and the magnetic assembly layer, the first connecting layer is used for fixedly connecting the switch assembly layer with the magnetic assembly layer, and the first connecting layer is made of an insulating material; the switch assembly layer, the first connecting layer and the magnetic assembly layer are integrally formed through pressing to form an assembly body;
the metal interconnection layer is arranged on a surface of the assembly body, the metal interconnection layer is provided with a plurality of different electrical properties, and the metal interconnection layer wraps at least a part of a top surface of the assembly body, at least a part of a side surface of the assembly body and at least a part of a bottom surface of the assembly body;
the switch assembly layer is electrically connected to the magnetic assembly layer by means of the metal interconnection layer.

2. The power supply module of claim 1, wherein the switch assembly layer comprises a switch unit, an input capacitor and a first metal wiring layer, the first metal wiring layer is electrically connected to pins of the switch unit and the input capacitor, and the first metal wiring layer is disposed adjacent to the first connecting layer and extends to a side surface of the assembly body and is electrically connected with the metal interconnection layer.

3. The power supply module of claim 1, wherein the magnetic assembly layer comprises an inductor, an inner hole and a second metal wiring layer, the inductor comprises a winding and a magnetic core, the winding is electrically connected with the second metal wiring layer through the inner hole, and the second metal wiring layer is arranged adjacent to the first connecting layer and extends to the side surface of the assembly body and is electrically connected with the metal interconnection layer.

4. The power supply module of claim 1, wherein the switch assembly layer comprises a switch unit layer, an input capacitor connection layer and an input capacitor layer, the input capacitor connection layer is arranged between the switch unit layer and the input capacitor layer, and the input capacitor connection layer is used for fixedly connecting the switch unit layer with the input capacitor layer; the switch unit layer, the input capacitor layer and the magnetic assembly layer are respectively provided with pins with different electrical properties; and at least a part of the pins extend to the side surface of the assembly body through a metal wiring layer and are electrically connected with the corresponding metal interconnection layer.

5. The power supply module of claim 1, wherein the power supply module further comprises a first bonding layer, the first bonding layer is arranged in the first connecting layer, the first bonding layer is used for cross-layer electrical connection of the switch assembly layer and the magnetic assembly layer, a material of the first bonding layer is a conductive high-melting-point material, and a melting point of the first bonding layer is higher than a highest temperature of welding.

6. The power supply module of claim 1, wherein the power supply module further comprises an output capacitor layer and a second connection layer, the second connection layer is arranged between the output capacitor layer and the magnetic assembly layer, the second connection layer is used for fixedly connecting the output capacitor layer with the magnetic assembly layer, and the second connection layer is made of an insulating material.

7. The power supply module of claim 6, wherein the output capacitor layer comprises an output capacitor, and the output capacitor layer is provided with a first surface and a second surface which are opposite to each other; the first surface is adjacent to the second connection layer, and a pin of the output capacitor layer is arranged on the second surface.

8. The power supply module of claim 6, wherein the output capacitor layer is provided with a plurality of layers stacked layer by layer; a switch unit layer, the magnetic assembly layer and the output capacitor layer are respectively provided with pins with different electrical properties; and at least a part of the pins extend to the side surface of the assembly body through a metal wiring layer and are electrically connected with the corresponding metal interconnection layer.

9. The power supply module of claim 6, wherein the magnetic assembly layer comprises an inductor, an output end inner hole and an output metal wiring layer, and the inductor comprises a winding and a magnetic core; and the winding is electrically connected with the output metal wiring layer through an inner hole of the output end; and the output metal wiring layer horizontally extends to the side surface of the assembly body and is electrically connected with the metal interconnection layer; and the inner hole of the output end, the output metal wiring layer and the metal interconnection layer form a first output conductive path; the power supply module further comprises a second bonding layer, the second bonding layer is arranged in the second connection layer, the positions of the inner hole of the output end, the second bonding layer and the winding vertically correspond, the inner hole of the output end and the second bonding layer form a second output conductive path; and the first output conductive path and the second output conductive path are connected in parallel; and a material of the second bonding layer is a conductive high-melting-point material, and a melting point of the second bonding layer is higher than a highest temperature of the power supply module welded with the system board.

10. The power supply module of claim 9, wherein the output capacitor layer comprises a copper column, the positions of the output end inner hole, the second bonding layer and the copper column vertically correspond, the output end inner hole, the second bonding layer and the copper column form a second output conductive path; and the first output conductive path and the second output conductive path are connected in parallel.

11. The power supply module of claim 6, wherein the switch assembly layer, the first connecting layer, the magnetic assembly layer, the second connection layer and the output capacitor layer are integrally formed through lamination.

12. The power supply module of claim 1, wherein the metal interconnection layer comprises a GND interconnection layer, a Vin+interconnection layer, a plurality of SW interconnection layers, a plurality of Vo+interconnection layers and a plurality of signal interconnection layers; the switch assembly layer comprises a plurality of switch units; the magnetic assembly layer comprises an inductor, and the inductor comprises a magnetic core and a plurality of windings; and the switch units, the SW interconnection layers, the windings and the Vo+interconnection layers are in one-to-one correspondence.

13. The power supply module of claim 11, wherein the power supply module is provided with a first side surface, a second side surface, a third side surface and a fourth side surface which are adjacent in sequence; the GND interconnection layer covers at least a part of the second side surface, the Vin+interconnection layer covers at least a part of the first side surface and at least a part of the third side surface, and one of the signal interconnection layers covers at least a part of the fourth side surface; and one of the SW interconnection layer and one of the Vo+interconnection layer are arranged at corners defined by the Vin+interconnection layer and the GND interconnection layer.

14. The power supply module of claim 12, wherein the magnetic assembly layer comprises an inductor, a plurality of inner holes and a plurality of second metal wiring layers, and each inductor comprises a winding, a magnetic core and at least two inductor integrated copper foils; the inductor is electrically connected with one of the second metal wiring layers through an inner hole, and one of the second metal wiring layer is arranged on a top surface of the magnetic assembly layer and extends to the side surface of the assembly body and is electrically connected with the metal interconnection layer; and one of the inductor integrated copper foils includes a first inductor integrated copper foil and a second inductor integrated copper foil; and the inductor is provided with a first inductor side surface, a second inductor side surface, a third inductor side surface and a fourth inductor side surface corresponding to a directions of the fourth side surface of the power supply module; the first inductor integrated copper foil wraps at least a part of the second inductor side surface; the second inductor integrated copper foil wraps at least a part of the fourth inductor side surface; an input end of the winding is electrically connected from a top surface of one of SW interconnection layers of the magnetic assembly layer; the first inductor integrated copper foil is electrically connected with the Vin+interconnection layer; and the second inductor integrated copper foil is electrically connected with the GND interconnection layer.

15. The power supply module of claim 13, wherein at least a part of the first side surface of the inductor is wrapped by one of a first inductor integrated copper foil or a second inductor integrated copper foil; and at least a part of the third side surface of the inductor is wrapped by one of a first inductor integrated copper foil or a second inductor integrated copper foil.

16. The power supply module of claim 13, wherein the magnetic assembly layer further comprises a plurality of output inner holes and a plurality of output metal wiring layers; the inductor is electrically connected with one of the output metal wiring layer through an output inner hole, and one of the output metal wiring layer is arranged on a bottom surface of the magnetic assembly layer and extends to the side surface of the assembly body and is electrically connected with the metal interconnection layer; an output end of the winding is electrically connected with one the Vo+interconnection layers from the bottom surface of the magnetic assembly layer; the first inductor integrated copper foil is electrically connected with the Vin+interconnection layer from the top surface and the bottom surface of the magnetic assembly layer, respectively; and the second inductor integrated copper foil is electrically connected with the GND interconnection layer from the top surface and the bottom surface of the magnetic assembly layer.

17. An integrated module with high heat dissipation capability and high reliability is characterized by comprising 2N power supply modules of claim 1; the power supply modules are electrically connected in parallel; the power supply modules are paired in pairs, each pair of power supply modules share one side surface, the metal interconnection layer comprises a signal interconnection layer, and the signal interconnection layer is arranged on a shared side surface; and N is a natural number.

18. The integrated module of claim 16, wherein a connection position is arranged between two adjacent pairs of power supply modules, and the connection position is made of an insulating material.

19. The integrated module of claim 16, wherein the signal interconnection layer is a through-hole electroplated layer.

20. The integrated module of claim 17, wherein a signal wiring layer is arranged at a bottom of the signal interconnection layer, and the signal wiring layer is used for summarizing a wiring of the signal interconnection layer of each power supply module.

21. The integrated module of claim 17, wherein a pin wiring layer is arranged at a bottom of the integrated module.

22. The integrated module of claim 16, wherein a welding ball is arranged at a bottom of one of the power supply modules, the welding ball includes at least four supporting welding balls, and the at least four supporting welding balls are arranged at four corners of a bottom of the integrated module.

23. The integrated module of claim 21, wherein one of the support welding balls is a copper alloy ball coated with a tin layer.
